(19) United States
(12) Patent Application Publication
(10) Pub. No.: US 2006/0147734 A1
(43) Pub. Date: Jul. 6, 2006

(54) Aqueous coating solutions and method for the treatment of a metal surface

(75) Inventors: Ivan Stewart Cole, Kew (AU); Damian Fullston, Dingley (AU); Scott Anthony Furman, Cranbourne South (AU); Tim Harvey Muster, Clayton (AU); Aaron Kiffer Neufeld, Chelsea (AU); Frankie Kok Wai Chan, Ferntree Gully (AU); Natalie Sherman, Caulfield North (AU)

Correspondence Address: SUGHRUE MION, PLLC, 2100 PENNSYLVANIA AVENUE, N.W., SUITE 800, WASHINGTON, DC, 20037, US

(73) Assignee: COMMONWEALTH SCIENTIFIC AND INDUSTRIAL RESEARCH OR, Campbell (AU)

(21) Appl. No.: 10/537,823

(22) PCT Filed: Dec. 9, 2003
(86) PCT No.: PCT/AU03/01644

§ 371 Date: Jan. 18, 2006

(30) Foreign Application Priority Data
Dec. 9, 2002 (AU) 2002953190

(51) Int. Cl. C08L 1/08; C09D 1/00; C04B 28/26; C03C 27/02; C03C 27/04; C09K 17/40; H01L 21/316; C23C 16/40; B32B 15/04

(52) U.S. Cl. 428/469; 428/472.2; 428/630; 428/631; 106/623; 106/635; 106/600; 106/286.4; 106/286.5; 106/286.1; 106/287.18; 106/287.17; 106/287.19; 106/287.34; 106/142.1

(57) ABSTRACT

A coating solution for providing a corrosion resistant coating to a metal surface including: a water soluble silicate; and at least one metal ion (X) selected from those having a valence of less than or equal to +4; wherein said coating solution forms an aqueous silicate-X network such that the silicate remains soluble, and wherein on contact with a metal surface (Y) a coating comprising of silicate-X and Y is formed.

The present invention relates to an aqueous coating solution and methods for the treatment of a metal surface. Metal surfaces treated with such coating solutions and/or by such methods are also provided.

More particularly, the invention relates to coating solutions which provide corrosion resistance to metal surfaces by forming a silicate network on the metal surface which has at least some Si atoms of the silicate network replaced by other metals ions having a valence of less than or equal to +4. This replacement imparts ion-exchange abilities to the network and helps maintain surface charge down to low pH values of around 3 (Iler, 1979). These properties lead to a number of significant advantages and in particular they permit the incorporation of additional metal cations into the network.

The coating of metal surfaces to impart corrosion resistance to the substrate is known. So called “conversion coatings”, and in particular chromium conversion coatings have been used for corrosion protection of iron, magnesium, aluminium, zinc and their alloys for over 50 years (Cotell et al., 1999). Conversion coatings are generally easily applied, are applicable to a wide range of metals and alloys and under certain conditions provide excellent adhesion for primers and paints.

Chromate conversion coatings are generally superior in their corrosion protection as they have a “self-healing” nature (Zhao et al., 2001). That is, they provide active corrosion protection. Chromate conversion coatings provide active corrosion protection in that chromium(VI) is released from the coating, a mixture of hydrated amorphous Cr(III)-Cr(VI) oxides, transported through the corrosive solution as soluble Cr(VI) oxy-anions, and reduced at the site of the damage. Active corrosion protection is critical where the conversion coating is the primary protection against corrosion. Such protection is maintained even if the treated surface is subject to minor mechanical or chemical damage.

However, chromium is considered a toxic substance, the hexavalent form being a known carcinogen which is environmentally hazardous as a waste product. Indeed, current legislation is moving towards the total exclusion of Cr(VI) and its use in the metal finishing industry is therefore limited. As a result, moves have been made to develop chromium free conversion coatings, including coatings based on silicates, zirconium, titanium, cerium, phosphates, permanganates and hydrotalcites (Gray, 2002). Unfortunately, few of these coatings exhibit comparable corrosion protection to chromate based systems and their use has therefore been limited to some extent. Among the most promising candidates being considered as active corrosion inhibitors are cerium compounds, permanganates, molybdates, vanadates and phosphates (Sinko, 2001).

It has been found that sealed complex oxides, such as Ce or Mn sealed lithium-hydrotalcite, can exhibit active corrosion protection on aluminium alloys (Buchheit et al., 2000). However rare earth conversion coatings have generally relied on the role of the rare earth in inhibiting the cathodic reaction, and to a lesser extent forming a stable oxide (Hinton, 1995).

Advantageously, the present invention is able to treat a metal surface to establish a coating that provides a predetermined surface chemistry that improves corrosion resistance. Further, the invention advantageously provides methods that may be used in existing treatment facilities and existing treatment baths with minimal alteration to those facilities.

According to one aspect of the invention there is provided a coating solution for providing a corrosion resistant coating to a metal surface. The coating solution includes a water soluble silicate and at least one metal ion (X) selected from those having a valence of less than or equal to +4, which then forms an aqueous silicate-X network such that the silicate remains soluble. When a metal surface (Y) comes in contact with this solution a coating consisting of silicate-X and Y is formed in part because of the ion-exchange properties of the silicate-X network.

Generally speaking, the coating layer provides the surface of the substrate with a predetermined pH_{IEP}, being the pH where the net surface charge is zero as measured by IEP (Isoelectric Point), such that at pH values greater than the pH_{IEP} the surface is negatively charged and will therefore repel negatively charged ions. If a variation occurs in the cross-sectional composition of the coating, it should be controlled so that the pH_{IEP} of the coating is lowest at the atmosphere-coating surface and highest at the coating-metal interface. Preferably the coating solution is composed such that the resulting coating layer on the metal surface has a pH_{IEP} of less than about 3.5 (at the atmosphere-coating interface) such that with surface waters at a pH of greater than 3.5 the coated surface of the metal is negatively charged. Even more preferably, the resulting coating layer has a pH_{IEP} of less than 2.5 at the atmosphere-coating interface.

It has been recognised by the present inventors that the coating solutions, as outlined, create a coating over the metal surface that provides a negative surface charge at most pH values, particularly at pH values greater than 3.5 and in some embodiments as low as 2-2.5. It is noted in this regard that acid rain has a pH of about 3. As the charge on the coated metal surface is negative at pH values above the pH_{IEP}, negatively charged species in the surface water, such as chloride, sulfate and nitrate ions, are repelled by the surface (Kendig, 1999; Sato, 1989). This helps inhibit corrosion of the substrate. The magnitude of the negative charge on the coated surface at pH 3 becomes larger as the pH_{IEP} is lowered, resulting in stronger repulsion of corrosive negative ions. Typical pH_{IEP} values of common phosphate and chromate(III) chemical conversion coatings are in the range of 5.6 and 7.0, respectively (Reinhard, 1987; Sato, 1989).

The water soluble silicate is not particularly limited in its selection provided that it is capable of forming a network which may exchange at least some of the Si atoms with metal ions X. Preferably, the water soluble silicate is selected from an alkali metal or ammonium silicate, meta-silicate, ortho-silicate, pyro-silicate, waterglass, silicic acid, silica, colloidal silica, silicon dioxide or an organic-silicate precursor. More particularly, the silicate is preferably selected from the group consisting of sodium silicate or potassium silicate from the practical point of view.

Similarly, the selection of the metal ion X is not particularly limited, provided that the metal ion has a valence of less than or equal to +4, and can be incorporated into the silicate matrix. Preferably, the metal ion is of an element selected from the group consisting of Al, B, Zr and Ti.

The coating solution may have a concentration of water soluble silicate from 1 ppm to the dispersion limit and a ratio of X to Si from 4:1 to 1:100. Preferably the ratio of X to Si is from 1:1 to 1:50.

In a particular preferred embodiment, the solution includes one or more optional additional components as a potential “active” corrosion inhibitor, preferably selected from the rare earths (lanthanides) or the transition metals (as defined in Cotton et al., 1999), such as but not limited to Ce, Mo, W, Mn or V, but most preferably Ce. It has been found that additional ions such as cerium ions assist in balancing the ion exchange abilities of the metal ion X substituted silicate in aqueous solution and are incorporated into the coating structure in such a way that the ions, such as cerium ions, are held within the coating until coating breakdown occurs. However, some of the bound cerium is able to be ion-exchange and therefore provide active corrosion protection.

According to another aspect of the present invention there is provided a method for the treatment of a metal surface, including applying to the metal surface an aqueous coating solution containing a water soluble silicate and at least one metal ion X selected from those having a valence of less than or equal to +4, thus forming a coating layer on the metal surface having a silicate network with at least some of the Si atoms in the silicate network being replaced with said metal ions X and incorporating metal ions Y from the metal surface being coated.

The various options as discussed above relating to the solution composition of the invention also apply to this aspect of the invention.

In one particular embodiment, the treatment of the metal surface includes applying to the metal surface an aqueous solution comprised of silicate ions and aluminium ions to coat the surface of the metal substrate with an aluminosilicate coating. In this embodiment, the metal surface preferably includes a zinc-containing metal surface, which may be zinc, a zinc alloy or a galvanised metal surface. In this embodiment, as the aluminosilicate coating binds to the metal surface, zinc ions may diffuse into the aluminosilicate coating structure so as to form a matrix including silicate ions, aluminium ions and diffused zinc ions. It is also envisaged that other metal substrates may provide a similar mechanism for providing a preferred corrosion resistant coating. For example, the metal surface may include aluminium, magnesium, copper, iron, titanium or their alloys. The metal surface refers to the surface of the metal, an alloy of the metal or a metal or its alloy coated on a different substrate.

According to one embodiment, an aluminosilicate coating having a pH_{IEP} from 2 to 2.5 is applied to the metal surface from an aqueous solution containing silicate ions and aluminium ions. This may be achieved by any suitable means. For example by spraying, painting or dipping. In a preferred embodiment, an aqueous solution comprised of silicate ions and aluminium ions, and further including Ce(IV)/Ce(III) ions as an optional additional corrosion inhibitor, is applied to the metal surface. In one embodiment, zinc metal, or zinc containing metal, is dipped in the above solution. This results in the production of zinc ions at the metal surface forming a diffusion layer. The pH in the diffusion layer near the metal surface rises and results in the formation of an aluminosilicate coating on the metal surface. The zinc ions in the diffusion layer are incorporated into the aluminosilicate coating to form a stable matrix comprised of aluminium, silicon, zinc, and cerium oxides.

Thus, according to a preferred embodiment of the invention, the method includes dipping a zinc-containing metal in an aqueous solution comprised of silicate ions and aluminium ions, and optionally including cerium ions, to form a diffusion layer at the metal surface, and for a time sufficient for an aluminosilicate coating to form on the metal surface. The aluminosilicate coating including within its structure zinc ions diffused from the zinc-containing metal surface, and optionally cerium ions.

According to another embodiment, an aqueous solution comprised of silicate ions and aluminium ions, preferably containing cerium ions, is prepared and a galvanized metal surface, such as galvanized steel, is dipped into a bath of the aqueous solution. Preferably, the galvanized metal surface is a freshly galvanized metal surface straight out of the molten zinc bath and quenched in the aqueous coating solution. The aqueous coating solution being used as a quench bath for the hot galvanized item. The aqueous coating quench bath is thereby heated upon dipping of the hot galvanized substrate into the bath. The above-described mechanism including diffusion and incorporation of zinc ions into the aluminosilicate coating is considered to hold true according to this embodiment of the invention.

An example of the coating composition that results from a preferred embodiment is Al₍ₐ₎Si_{(b)}Zn_{(c)}Ce_{(d)}Oₓ where 0<a≦1, 0<b≦1, 0<c≦1, 0≦d≦1 and a+b+c+d=1, with the overall concentration of the aqueous components ranging from 1 ppm to 20 wt %.

According to a further aspect of the invention there is provided a metal surface having an aluminosilicate coating, the coating further including diffused metal ions, which have diffused from the metal surface into the aluminosilicate coating during application of the coating to the metal surface. The coating that results has a pH_{IEP} of less than 3.5 at the atmosphere-coating surface and is thus capable of repelling anions in surface water of pH values greater than 3.5.

It will be understood that this aspect of the invention follows from the above-described methods of treatment and coating. As such, the preferred features as described above also apply to this aspect of the invention.

In this regard, in a particular embodiment, the metal surface includes a zinc-containing surface and the aluminosilicate coating preferably includes cerium ions as an optional additional corrosion inhibitor.

Embodiments of the invention will now be exemplified in more detail. These examples are provided for exemplification only and should not be construed as limiting on the invention in any way.

### EXAMPLE 1

The performance of a cerium containing aluminosilicate coating on room temperature pure rolled zinc plates was determined in a 290 hour neutral salt spray (NSS) test and compared to blank uncoated zinc (Table 1). The coating was formed from a 10 minute immersion in a 1% solution with an elemental ratio of 1:1:5 with respect to Ce, Al and Si. The NSS test was conducted according to AS 2331 with number of pits visible to the naked eye and mass loss results averaged from three replicate samples. The plates were 10 cm×15 cm and 1 mm thick.

TABLE 1
Coating performance in 290 hour NSS on pure rolled zinc plates.

| | | Average Mass Loss |
|---|---|---|
| Sample | Average # Pits/Plate | (g/m²/day) |
| CSIRO Coating 1 | 25 | 7.8 |
| Blank Zinc | 90 | 15.7 |

### EXAMPLE 2

Pure rolled zinc plates were heated to 200° C. before being quenched in the coating solutions and assessed by NSS as in example 1 (Table 2). The CSIRO Coatings 2, 3 and 4 were from 1% solutions with an elemental ratio of 1:1:5 with respect to Ce, Al and Si, with the solutions forming coatings 3 and 4 containing a majority of Ce(IV) ions through addition of hydrogen peroxide. CSIRO Coatings 2 and 3 were immersed in the coating solution for 2 minutes, while CSIRO Coating 4 was immersed for 5 seconds. Chromate Coating 1 was formed by a 2 minute immersion in a 0.16% chromate solution made from sodium dichromate.

TABLE 2
Coating performance in 312 hour NSS on heated pure
rolled zinc plates.

| | | Average Mass Loss |
|---|---|---|
| Sample | Average # Pits/Plate | (g/m²/day) |
| CSIRO Coating 2 | 90 | 23.3 |
| CSIRO Coating 3 | 15 | 19.5 |
| CSIRO Coating 4 | 0 | 8.0 |
| Chromate Coating 1 | 90 | 22.3 |
| Blank Zinc | 90 | 23.1 |

### EXAMPLE 3

Coating performance on pure rolled zinc plates was assessed using a 500 hour NSS test (as in examples 1 and 2), a 2 year field exposure and paint adhesion (Table 3). The average salt deposition for the marine field exposure site is about 100 mg/m² day as measured according to ISO 9225 and results are averaged from three plates. Plates were painted with silicone-enriched epoxy enamel after drying the coatings for 1 day at room temperature. Paint adhesion was performed one week after painting and was of the crosscut tape pull type in three positions on one plate. CSIRO Coating 5 was from a room temperature plate immersed in a 1% 1:1:5 ratio Ce:Al:Si solution for 2 minutes. CSIRO Coatings 6, 7 and 8 were from 200° C. heated plates immersed in 1:1:5 ratio Ce:Al:Si solutions for 15 seconds. CSIRO Coatings 6 and 7 were from 1% solutions, while 8 was from a 0.1% solution. CSIRO Coating 6 was from a predominantly Ce(III) solution. Chromate Coating 2 was from a 200° C. plate immersed for 15 seconds in a 0.16% chromate solution made from sodium dichromate. Blank Galvanized Z275 was a commercially available galvanized steel sheet for comparison.

TABLE 3
Coating performance in 500 hour NSS, 2 year field exposure
and paint adhesion tests on pure rolled zinc plates.

| | | | Field Exposure | | |
|---|---|---|---|---|---|
| | | | Performance | | |
| | NSS Performance | | | Average | Paint |
| | Average | Average | Average | Corrosion | Adhesion |
| | # Pits/ | Mass Loss | Mass Loss | Rate | % Paint |
| Sample | Plate | (g/m²/day) | (mg/m²/day) | (μm/year) | Removed |
| CSIRO | 1 | 5.2 | 81.4 | 4.2 | <5 |
| Coating 5 | | | | | |
| CSIRO | 5 | 5.6 | 58.5 | 2.9 | 35-65 |
| Coating 6 | | | | | |
| CSIRO | 5 | 6.5 | 56.1 | 3.0 | 0 |
| Coating 7 | | | | | |
| CSIRO | 80 | 15.1 | 75.7 | 3.9 | 0 |
| Coating 8 | | | | | |
| Chromate | 5 | 5.8 | 62.9 | 3.2 | 5-15 |
| Coating 2 | | | | | |
| Blank Zinc | 70 | 15.6 | 76.6 | 3.9 | 5-15 |
| Blank Gal- | 20 | 8.5 | 87.1 | 4.4 | 15-35 |
| vanized | | | | | |
| Z275 | | | | | |

### EXAMPLE 4

Galvanized steel quench coating performance of cerium containing aluminosilicate coatings were compared to chromate coatings in both neutral salt spray and stack tests (Table 4). Galvanized steel quench coating involved immersing the cleaned and fluxed (zinc ammonium chloride) steel plate in molten zinc at 450° C. to galvanizes the sample, and upon withdrawal, immersing the hot sample in the quench coating solution for five seconds. The cerium containing aluminosilicate coating (CSIRO Galv Quench 1) was formed from a 0.1% solution with an elemental ratio of 1:1:5 with respect to Ce, Al and Si. The Chromate quench was carried out in a standard 0.05% chromate quench solution made from sodium dichromate. The NSS test was for 72 hours and conducted as per previous examples, while the “stack” test was an industrial specification with the following details. Two sets of paired plates are stacked together and placed in a 100% RH chamber and cycled between 25° C. (6 hours) and 10° C. (2 hours) for 30 cycles (240 hours). The steel plates were 10 cm×15 cm, and 1 mm thick before galvanizing. The results demonstrates that the CSIRO quench coating gave performance that matched the standard chromate quench coating while both preformed significantly better than the water quenched galvanised steel samples.

TABLE 4
Galvanized steel quench coating performance in 72 hour NSS
and 240 hour stack tests.

| | | | Stack Test |
|---|---|---|---|
| | NSS Performance | | Average |
| | Average # Pits/ | Average Mass | Mass Gain |
| Sample | Plate | Loss (g/m²/day) | (mg) |
| CSIRO Galv Quench 1 | 0 | 2.7 | 1.5 |
| Galv Chromate Quench 1 | 3 | 4.0 | 2.0 |
| Galv Water Quench 1 | * | 34.2 | 49.6 |

*Significant zinc removal so number of pits can not be counted

### EXAMPLE 5

Galvanized quench coating performance of different solution compositions was tested with NSS and condensation tests (Table 5) as per example 4, except the “stack” test was modified to a “condensation” test in which two sets of only one plate was used, everything else being the same. A synergistic effect between silicate ions and aluminium ions can clearly be seen in either acidic or alkaline conditions. CSIRO Galv Quench 2 was a 0.1% 1:1:5 ratio Ce:Al:Si solution and Galv Chromate Quench 2 was a standard 0.05% chromate quench solution made from sodium dichromate.

TABLE 5
Galvanized steel quench coating performance in 72 hour NSS
and 240 hour condensation tests.

| | | | Condensation |
|---|---|---|---|
| | NSS Performance | | Test |
| | | Average Mass | Average |
| | Average # Pits/ | Loss | Mass Gain |
| Sample | Plate | (g/m²/day) | (mg) |
| Basic Silicate Ions | 20 | 10.7 | 71.6 |
| Acidic Silicate Ions | 2 | 9.3 | 26.7 |
| Acidic Aluminium | * | 36.8 | 6.2 |
| Ions | | | |
| Basic Aluminium Ions | * | 34.5 | 45.1 |
| Acidic Silicate + | 0 | 2.8 | 8.7 |
| Aluminium Ions | | | |
| Basic Silicate + | 0 | 5.1 | 23.4 |
| Aluminium Ions | | | |
| CSIRO Galv Quench 2 | 0 | 1.9 | 16.6 |
| Galv Chromate | 5 | 8.3 | 0 |
| Quench 2 | | | |

*Significant zinc removal so number of pits can not be counted

### EXAMPLE 6

Galvanized steel quench coating performance was tested as a function of sample immersion time in the quench solution by NSS and condensation tests as per example 5 (Table 6). The CSIRO quench solutions were a 0.1% 1:1:5 ratio Ce:Al:Si solution and the Chromate quench solution was a standard 0.05% chromate solution.

TABLE 6
Galvanized steel quench coating performance in 72 hour NSS
and 240 hour condensation tests as a function of immersion
time in quench solution.

| | | NSS Performance | | Condensation Test |
|---|---|---|---|---|
| | | | Average Mass | Average Mass |
| | Immersion | Average # | Loss | Gain |
| Sample | Time (s) | Pits/Plate | (g/m²/day) | (mg) |
| CSIRO | 5 | 0 | 1.6 | 8.7 |
| CSIRO | 30 | 0 | 2.0 | 13.6 |
| CSIRO | 90 | 0 | 2.1 | 9.5 |
| Chromate | 5 | 5 | 1.0 | 7.2 |

### EXAMPLE 7

Galvanized steel quench coating performance was assessed by paint adhesion tests as a function of time after quenching before painting. Quench coated samples were atmospherically dried under laboratory conditions (about 18° C. and 50% RH) for up to 3 months before being painted and tested as per example 3 (Table 7). CSIRO Galv Quench 3 was a 0.1% 1:1:5 ratio Ce:Al:Si solution, while Galv Chromate Quench 3 was a 0.05% chromate solution from sodium dichromate. It can be clearly seen that the current technology provides substantial benefits over the standard chromate quench coating in terms of quench coating stability over time before applying the paint coating.

TABLE 7
Paint adhesion performance of galvanized steel quench coating
as function of drying time before applying the paint coating.

| | % Paint Removed | | | | | |
|---|---|---|---|---|---|---|
| | 1 | 2 | 1 | 1 | 2 | 3 |
| Sample | day | days | week | month | months | months |
| CSIRO Galv | 0 | 0 | 0 | 0 | 0 | <5 |
| Quench 3 | | | | | | |
| Galv Chromate | 0 | <5 | 15-35 | >65 | >65 | >65 |
| Quench 3 | | | | | | |
| Water Quench | >65 | >65 | >65 | >65 | 35-65 | <5 |
| Air Cooled | >65 | >65 | >65 | >65 | 15-35 | 5-15 |

### EXAMPLE 8

Galvanized steel quench coating performance was tested as a function of aluminium content in the molten zinc galvanizing bath and assessed using NSS and condensation testing as per examples 5 and 6 (Table 8). CSIRO Galv Quench samples were from 0.1% 1:1:5 ratio Ce:Al:Si solutions, while Galv Chromate Quench samples were from standard 0.05% chromate solutions. The current technology allows for a greatly broadened melt aluminium content operating window for the galvanizer.

TABLE 8
Galvanized steel quench coating performance in 72 hour NSS
and 240 hour condensation tests as function of aluminium
content in the molten zinc galvanizing bath.

| | | | | Condensation |
|---|---|---|---|---|
| | | NSS Performance | | Test |
| | | | Average Mass | Average Mass |
| Al | | Average # | Loss | Gain |
| (ppm) | Sample | Pits/Plate | (g/m²/day) | (mg) |
| 98 | CSIRO Galv | 2 | 3.1 | 0 |
| | Quench 4 | | | |
| 93 | Galv Chromate | * | 50.3 | 0 |
| | Quench 4 | | | |
| 45 | CSIRO Galv | 0 | 1.9 | 16.6 |
| | Quench 5 | | | |
| 48 | Galv Chromate | 5 | 8.3 | 0 |
| | Quench 5 | | | |
| 3 | CSIRO Galv | 0 | 1.6 | 0.6 |
| | Quench 6 | | | |
| 3 | Galv Chromate | 2 | 0.8 | 0 |
| | Quench 6 | | | |

*Significant zinc removal so number of pits can not be counted

### EXAMPLE 9

Galvanized quench coating performance was tested on individually quenched square hollow sections (SHS) with dimensions of 25×25×1.6 mm and 20×20×2.0 mm by 150 mm long bundled together in a 3×3 matrix using the condensation test as per examples 5, 6 and 8 (Table 9). CSIRO Galv Quench 7 and 8 were 0.1% 1:1:5 ratio Ce:Al:Si solutions, while Galv Chromate Quench 7 and 8 were standard 0.05% chromate solutions. Average mass gain is for the nine bundled SHS samples.

TABLE 9
Galvanized steel quench coating performance on 3 × 3 bundled
SHS in a 240 hour condensation test.

| | SHS | |
|---|---|---|
| Quench Coating | Dimensions (mm) | Average Mass Gain (mg) |
| CSIRO Galv Quench 7 | 25 × 25 × 1.6 | 2.2 |
| Galv Chromate Quench 7 | 25 × 25 × 1.6 | 4.3 |
| CSIRO Galv Quench 8 | 20 × 20 × 2.0 | 10.4 |
| Galv Chromate Quench 8 | 20 × 20 × 2.0 | 9.7 |

### EXAMPLE 10

Cerium containing aluminosilicate coatings were applied to pure (>99%) metals of magnesium, aluminium, copper and iron and to aluminium alloy 2024, Galfan (Zn-5% AI) and Zincalume (Zn-55% Al) from solutions having a ratio of 1:1:5 for Ce:Al:Si. Coatings were visually confirmed and resistivity to chloride corrosion checked by depositing a single sodium chloride crystal on coated and un-coated surfaces and storing at 100% RH for 19 hours.

It is to be understood that, while the preferred embodiments of the invention have been described, it should be appreciated that the invention is susceptible to modifications without departing from the spirit or scope of the invention.

### REFERENCES

25 Buchheit, R. G., Mamidipally, S. B., Schmutz, P. and Guan, H. (2000). “Active corrosion protection in chromate and chromate-free conversion coatings”. In Proceedings of Corrosion 2000. Surface Conversions of Aluminium and Ferrous Alloys for Corrosion Resistance, NACE, USA.
Cotell, C. M., J. A. Sprague, et al. (1999). ASM Handbook, Volume 5, Surface Engineering, ASM International, Materials Park, Ohio, USA.
Cotton, F. A., Wilkinson, G., Murillo, C. A. and Bochmann, M. (1999). Advanced Inorganic Chemistry 6^{th} Ed., John Wiley & Sons, New York, USA.
Gray, J. E. and B. Luan (2002). “Protective coatings on magnesium and its alloys—a critical review.” Journal of Alloys and Compounds 336: 88-113.
Hinton, B. R. W. (1995). Corrosion prevention and control. Handbook on the Physics and Chemistry of Rare Earths. K. A. G. J. a. L. Eyring. Amsterdam, Elsevier. 21: 29-90.
Iler, R. K. (1979). The Chemistry of Silica, John Wiley and Sons.
ISO 9225 (1992) “Corrosion of Metals and Alloys—Corrosivity of Atmospheres—Measurement of Pollution”, International Organization for Standardization (Geneve).
Kendig, M., R. Addison, et al. (1999). “The influence of adsorbed Oxo-Cr(VI) species on the zeta potential in the porous oxide of anodized aluminium.” Journal of the Electrochemical Society 146(12): 4419-4423.
Reinhard, G. (1987). “Surface characterization of iron and steel prior to coating.” Progress in Organic Coatings 15: 125-148.
Sato, N. (1989). “Toward a more fundamental understanding of corrosion processes.” Corrosion 45(5): 354-368.
Sinko, J. (2001). “Challenges of chromate inhibitor pigments replacement in organic coatings.” Progress in Organic Coatings 42: 267-282.
Zhao J., L. Xia, et al. (2001). “Effects of chromate and chromate conversion coatings on corrosion of aluminium alloy 2024-T3.” Surface and Coatings Technology 140: 51-57.

1. An aqueous coating solution for providing a corrosion resistant coating to a metal surface including:
a water soluble silicate; and
at least one metal ion (X) selected from those having a valence of less than or equal to +4; wherein said coating solution forms an aqueous silicate-X network such that the silicate remains soluble, and wherein on contact with a metal surface (Y) a coating comprising of silicate-X and Y is formed.

2. A coating solution according to claim 1, wherein the coating solution is composed such that the resulting coating layer on the metal surface has a pH_{IEP} of less than about 3.5 at the atmosphere-coating interface.

3. A coating solution according to claim 2, wherein the coating solution is composed such that the resulting coating layer on the metal surface has a pH_{IEP} of less than 2.5 at the atmosphere-coating interface.

4. A coating solution according to claim 1, wherein the water soluble silicate is selected from an alkali metal or ammonium silicate, meta-silicate, ortho-silicate, pyro-silicate, waterglass, silicic acid, silica, colloidal silica, silicon dioxide or an organic-silicate precursor.

5. A coating solution according to claim 4, wherein the water soluble silicate is selected from the group consisting of sodium silicate or potassium silicate.

6. A coating solution according to claim t, wherein the metal ion X is of an element selected from the group consisting of Al, B, Zr and Ti.

7. A coating solution according to claim 1, having a concentration of water soluble silicate of from 1 ppm to the dispersion limit and a ratio of X to Si from 4:1 to 1:100.

8. A coating solution according to claim 7, wherein the ratio of X to Si is from 1:1 to 1:50.

9. A coating solution according to claim 1, including one or more additional components as a active corrosion inhibitor.

10. A coating solution according to claim 9, wherein said additional component(s) are selected from the rare earths (lanthanides) or the transition metals.

11. A coating solution according to claim 10, wherein said additional component(s) are selected from Ce, Mo, W, Mn and V.

12. A coating solution according to claim 11, wherein said additional component includes Ce.

13. A method for the treatment of a metal surface, including applying to the metal surface an aqueous coating solution containing a water soluble silicate and at least one metal ion X selected from those having a valence of less than or equal to +4, thus forming a coating layer on the metal surface having a silicate network with at least some of the Si atoms in the silicate network being replaced with said metal ions X and incorporating metal ions Y from the metal surface being coated.

14. A method according to claim 13, including applying to the metal surface an aqueous solution comprised of silicate ions and aluminium ions to coat the surface of the metal substrate with an aluminosilicate coating.

15. A method according to claim 14, wherein the metal surface includes a zinc-containing metal surface.

16. A method according to claim 15, wherein the metal surface includes zinc, a zinc alloy or a galvanised metal surface.

17. A method according to claim 14, wherein aluminosilicate coating having a pH_{IEP} from 2 to 2.5 is applied to the metal surface from an aqueous solution containing silicate ions and aluminium ions.

18. A method according to claim 17, wherein the solution is applied by spraying, painting or dipping.

19. A method according to claim 14, wherein an aqueous solution comprised of silicate ions and aluminium ions and further including Ce(IV)/Ce(III) ions as an additional corrosion inhibitor is applied to the metal surface.

20. A method according to claim 19, wherein zinc metal, or zinc containing metal is dipped in the aqueous solution.

21. A method according to claim 13, including dipping a zinc-containing metal in an aqueous solution comprised of silicate ions and aluminium ions, and optionally including cerium ions, to form a diffusion layer at the metal surface, and for a time sufficient for an aluminosilicate coating to form on the metal surface, the formed aluminosilicate coating including within its structure zinc ions diffused from the zinc-containing metal surface, and optionally cerium ions.

22. A method according to claim 21, wherein the zinc containing metal is a galvanized metal.

23. A method according to claim 22, wherein the galvanized metal is galvanized steel.

24. A method according to claim 22, wherein the galvanized metal includes a freshly galvanized metal surface straight out of the molten zinc bath and quenched in the aqueous coating solution.

25. A method according to claim 13, wherein the coating composition that results is Al₍ₐ₎Si_{(b)}Zn_{(c)}Ce_{(d)}Oₓ where 0<a≦1, 0<b≦1, 0<c≦1, 0≦d≦1 and a+b+c+d=1, with the overall concentration of the aqueous components ranging from 1 ppm to 20 wt %.

26. A metal surface having an aluminosilicate coating, the coating including diffused metal ions, which have diffused from the metal surface into the aluminosilicate coating during application of the coating to the metal surface, the coating having a pH_{IEP} of less than 3.5 at the atmosphere-coating surface.
